(19) United States
(12) Patent Application Publication
(10) Pub. No.: US 2015/0262696 A1
(43) Pub. Date: Sep. 17, 2015

(54) MEMORY SYSTEM AND CONTROL METHOD OF MEMORY SYSTEM

(71) Applicant: Kabushiki Kaisha Toshiba, Minato-ku (JP)

(72) Inventors: Akihiro SAKATA, Yokohama (JP); Norikazu YOSHIDA, Kawasaki (JP); Toshikatsu HIDA, Yokohama (JP); Yoshikazu TAKEYAMA, Fujisawa (JP); Shinichi KANNO, Ota (JP)

(73) Assignee: Kabushiki Kaisha Toshiba, Minato-ku (JP)

(21) Appl. No.: 14/475,929

(22) Filed: Sep. 3, 2014

Related U.S. Application Data
(60) Provisional application No. 61/951,937, filed on Mar. 12, 2014.

(51) Int. Cl. G11C 16/30; G11C 16/10; G11C 16/26

(52) U.S. Cl. CPC G11C 16/30; G11C 16/26; G11C 16/10

(57) ABSTRACT

According to one embodiment, a controller switches modes including a normal operating mode in which power resources of a volatile memory, a data storage unit, and a power control unit are all ON, a first mode in which the power resource of the volatile memory is OFF, and the power resources of the data storage unit and the power control unit are both ON, and a second mode in which the power resources of the volatile memory and the data storage unit are both OFF, and the power resource of the power control unit is ON. Upon receiving a low power consumption instruction command from a host, the controller stores management information to return to the normal operating mode into the volatile storage unit, and shifts the state of the memory system from the normal operating mode to the first mode.

### CROSS-REFERENCE TO RELATED APPLICATIONS

This application is based upon and claims the benefit of priority from U.S. Provisional Application No. 61/951,937, filed on Mar. 12, 2014; the entire contents of which are incorporated herein by reference.

### FIELD

Embodiments described herein relate generally to a memory system and a control method of the memory system.

### BACKGROUND

When there is no access from a host, a memory system including a non-volatile memory may be partially powered off to reduce power consumption. At this point in time, it is necessary to save data necessary for a restore in the non-volatile memory. In recent years, coordination between the host and the memory system has become complicated, and frequent state switching may be required in a short period of time. However, the frequent transition between power on and power off states leads to a reduction in the reliability of the non-volatile memory due to the frequent occurrence of data saving in the non-volatile memory, and to increases in the time taken for processing upon switching of the state and the overhead of power consumption. Hence, more efficient state transition is required for power on/off.

### BRIEF DESCRIPTION OF THE DRAWINGS

FIG. 1 is a diagram illustrating a configuration of a memory system according to an embodiment;

FIG. 2 is a diagram describing states that the memory system can enter and illustrating the relationship of transition of the states;

FIG. 3 is a diagram illustrating the progress of data movement between a memory controller and a data storage unit upon hibernation from a state a to a state b and a return from the state b to the state a;

FIG. 4 is a flowchart illustrating the operation of the memory system at the time of the transition from the state a to the state b;

FIG. 5 is a diagram illustrating the state of the data storage unit while management information is saved in data cache;

FIG. 6 is a flowchart illustrating the operation of the memory system including the transition from the state b to the state a;

FIG. 7 is a diagram illustrating the state of the data storage unit while reading out the management information saved in the data cache;

FIG. 8 is a diagram illustrating the progress of data movement between the memory controller and the data storage unit upon hibernation from the state a to the state b, and the transition from the state b to a state c;

FIG. 9 is a flowchart illustrating the operation of the memory system including the transition from the state b to the state c; and

FIG. 10 is a diagram illustrating the state of the data storage unit while writing the management information saved in the data cache to the non-volatile memory.

### DETAILED DESCRIPTION

In general, according to one embodiment, a memory system includes a data storage unit including a volatile storage unit and a non-volatile memory where data is read and written via the volatile storage unit, a volatile memory, a controller configured to control the reading and writing of data from and to the data storage unit, and a power control unit configured to control power supply to the controller, the volatile memory, and the data storage unit. According to the embodiment, the controller switches modes including a normal operating mode, a first mode, and a second mode. The normal operating mode is a mode in which power resources of the volatile memory, the data storage unit, and the power control unit are all ON. The first mode is a mode in which the power resource of the volatile memory is OFF, and the power resources of the data storage unit and the power control unit are both ON. The second mode is a mode in which the power resources of the volatile memory and the data storage unit are both OFF, and the power resource of the power control unit is ON. Upon receiving a low power consumption instruction command from a host, the controller stores management information into the volatile storage unit. The management information includes information to return to the normal operating mode, and shifts the state of the memory system from the normal operating mode to the first mode.

An exemplary embodiment of the memory system and a control method of the memory system will be explained below in detail with reference to the accompanying drawings. The present invention is not limited to the following embodiment.

### Embodiment

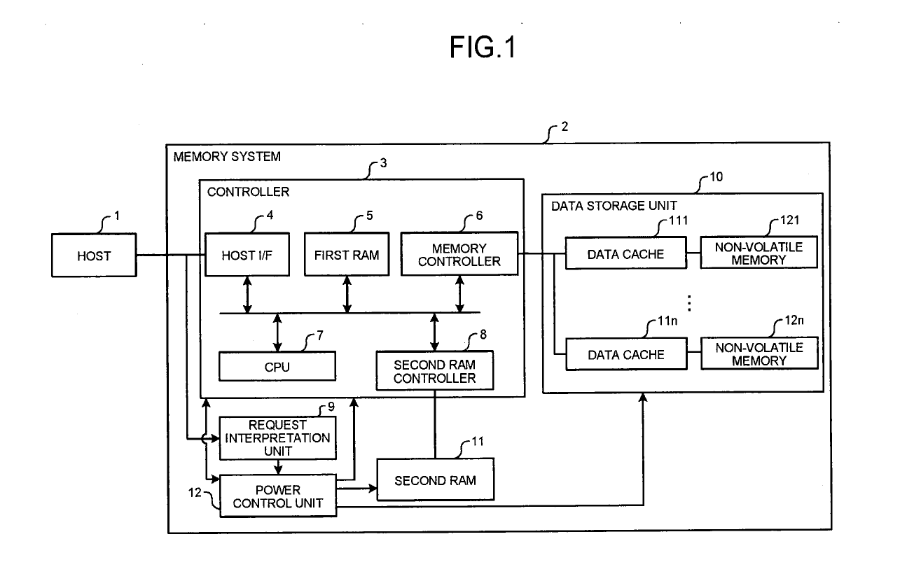

FIG. 1 is a diagram illustrating a configuration of a memory system 2 according to an embodiment. The memory system 2 includes a controller 3, a request interpretation unit 9, a data storage unit 10 such as a NAND flash memory, a second RAM 11 (a volatile memory) such as a DRAM, and a power control unit 12. The memory system 2 is connected to a host 1 such as a personal computer. The controller 3 includes a host I/F 4 that accepts a command from the host 1, a first RAM 5 (a volatile memory) as a buffer, a memory controller 6 that controls the data storage unit 10, a CPU 7, and a second RAM controller 8 that controls the second RAM 11. The first RAM 5 and the second RAM 11 may be provided in the same volatile memory. The data storage unit 10 includes data caches 111 to 11n (volatile storage units), and non-volatile memories 121 to 12n. Each of the data caches 111 to 11n is a volatile memory that once saves data to write or read data to or from each of the non-volatile memories 121 to 12n.

The power control unit 12 supplies and controls electric power from an external power source to the controller 3, the second RAM 11, and the data storage unit 10. The power control unit 12 is controlled by the controller 3 and the request interpretation unit 9. When a new command comes from the host 1 while the power resource of the controller 3 is OFF, the request interpretation unit 9 causes the power control unit 12 to start the controller 3. The request interpretation unit 9 may be included inside the controller 3.

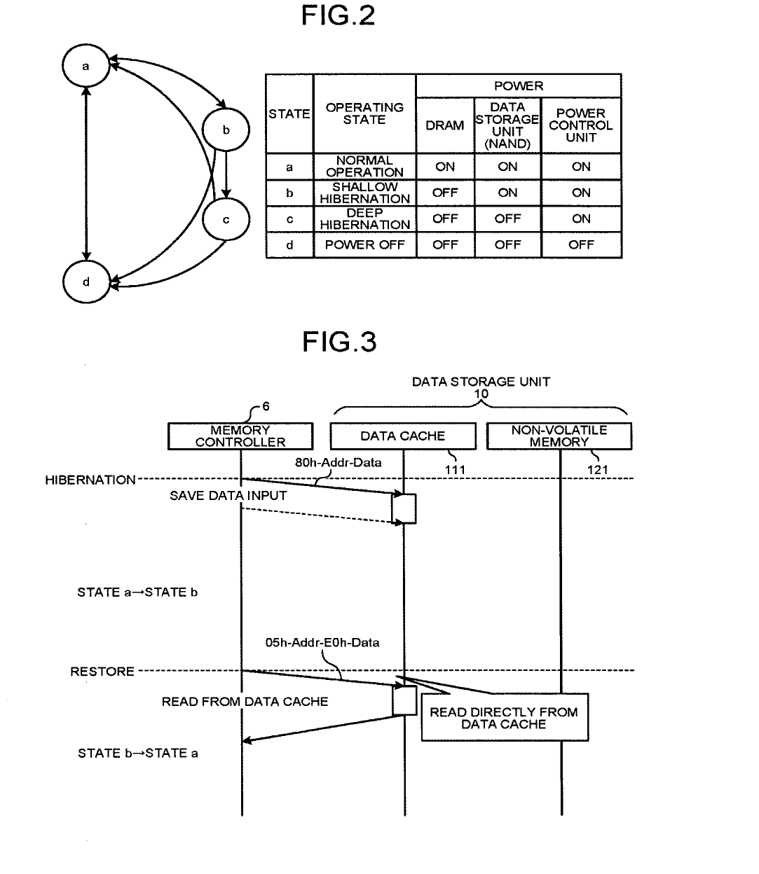

FIG. 2 is a diagram describing states that the memory system 2 can enter and illustrating the relationship of transition of the states. The memory system 2 has a plurality of states a (normal operating mode), b (shallow hibernation: first mode), c (deep hibernation: second mode), and d (power off), depending on whether the power resources of the second RAM 11, the data storage unit 10, and the power control unit 12 are ON or OFF. The state a is a state in which the power resources of the second RAM 11, the data storage unit 10, and the power control unit 12 are all ON. The state b is a state in which the power resource of the second RAM 11 is OFF and the power resources of the data storage unit 10 and the power control unit 12 are ON. The state c is a state in which the power resources of the second RAM 11 and the data storage unit 10 are OFF, and the power resource of the power control unit 12 is ON. The state d is a state in which the power resources of the second RAM 11, the data storage unit 10, and the power control unit 12 are all OFF. These states can be transitioned to each other as indicated by arrows. The transition from the state a to the state d occurs when the controller 3 receives a power-off request from the host 1. The transition from the states b and c to the state d occurs when the power control unit 12 receives a power-off request from the host 1. The transition from the state c to the state a occurs when the power control unit 12 receives a startup request from the host 1. The transition from the state d to the state a occurs at the time of normal power-on. The transition between the state a and the state b and the transition from the state b to the state c are described below.

If the controller 3 receives a low power consumption instruction command from the host 1 while the memory system 2 is in the state a, a process of removing power from the second RAM 11 is performed to enter the state b.

If power is further removed from the controller 3 in the state b, the controller 3 cannot receive a request from the host 1. Hence, when the controller 3 enters the hibernation state, the request interpretation unit 9 does not remove power from itself and monitors the host l's request to the controller 3. When detecting the host l's request to the controller 3, the request interpretation unit 9 notifies the power control unit 12. The power control unit 12 supplies power to the controller 3 and other components from which power has been removed. The components that have been supplied with power perform restoration processes.

In the hibernation/restoration process, there is a method for saving part or all of information necessary for restoration in a location from which the information can be read at the time of restoration for the purpose of reducing processing time and the number of accesses to the non-volatile memories 121 to 12n. For example, it is necessary in the state c to write, to the non-volatile memories 121 to 12n, information to be saved. In the embodiment, the state b is further provided between the state a and the state c.

FIG. 3 is a diagram illustrating the progress of data movement between the memory controller 6 and the data storage unit 10 upon the transition from the state a to the state b and the transition from the state b to the state a.

(State a→State b)

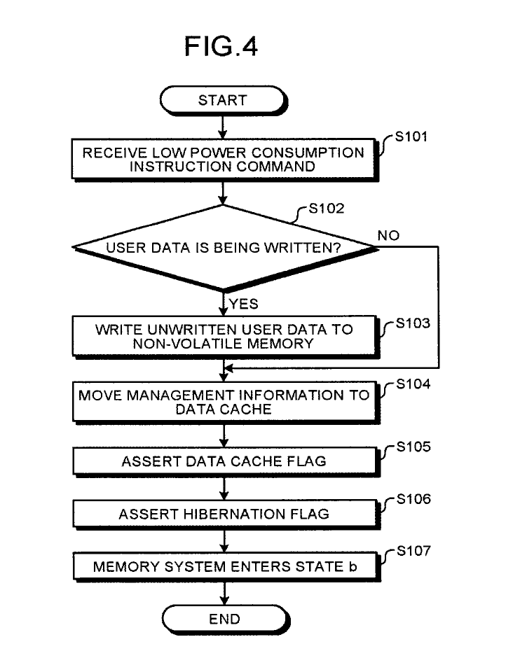

To begin with, a description is given of the progress of hibernation from the state a to the state b illustrated in the upper part of FIG. 3 with reference to the flowchart of FIG. 4. First, when the memory system 2 receives a low power consumption instruction command from the host 1 via the host I/F 4 while in the state a (Step S101), the memory system 2 determines whether or not user data is being written (Step S102). If user data is being written (Step S102: Yes), unwritten data saved in the first RAM 5 is written to the non-volatile memories 121 to 12n (Step S103) to end the write operation. If user data is not being written (Step S102: No), and after Step S103, the controller 3 saves management information existing in the first RAM 5 or the second RAM 11 as save data in the data cache 111 (Step S104). The management information is information to initialize the data storage unit 10 and firmware, which is necessary to return to the state a. For example, the management information includes part or all of information indicating internal states of the non-volatile memories 121 to 12n, information to manage addresses of data saved in the non-volatile memories 121 to 12n, an address translation table, or parameters set by the host 1.

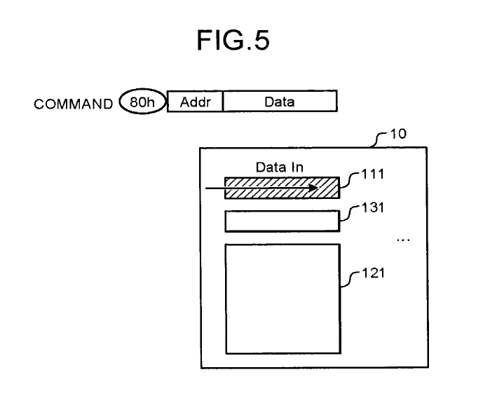

Step S104 is now described in detail. The memory controller 6 issues, to the data storage unit 10, a data input start command, for example, “80h-Addr-Data” illustrated in the upper parts of FIGS. 3 and 5. “80h” is a serial input command. “Addr” is an address on the non-volatile memory 121. “Data” represents data to be saved. The data storage unit 10, which has received the command, saves the management information as “Data” in the data cache 111. The memory controller 6 does not issue, to the data storage unit 10, a command to confirm a data write to the data storage unit 10 after “80h-Addr-Data” being the data input start command. Specifically, the command to confirm a data write is, for example, “10h” being a command to instruct the start of making data nonvolatile.

The memory controller 6 issues, to the data storage unit 10, the “80h-Addr-Data” command illustrated in the upper part of FIG. 5, and accordingly the management information is stored in the data cache 111 illustrated in the lower part of FIG. 5. “Data In” indicates that the data has been stored in the data cache 111. In more detail, as illustrated in the lower part of FIG. 5, the data storage unit 10 further includes a program buffer 131 as non-volatile memory, in addition to the data cache 111. The data of the data cache 111 is written to the non-volatile memory 121 via the program buffer 131. For example, it is configured such that if the data is once stored in the program buffer 131, the stored data is automatically written to the non-volatile memory 121. In Step S104, since the command to confirm a data write is not issued, the management information is simply saved in the data cache 111, and is not transferred to the program buffer 131. Therefore, the management information is not written to the non-volatile memory 121. The data storage unit 10 of the lower diagram of FIG. 5 includes the data caches 111 to 11n, n program buffers including the program buffer 131, and the non-volatile memories 121 to 12n. However, only the data cache 111, the program buffer 131, and the non-volatile memory 121 are illustrated.

After Step S104, a data cache flag indicating that the management information exists in the data cache 111 is asserted (Step S105). Furthermore, a hibernation flag indicating to be in the state b is asserted (Step S106). It is sufficient if the data cache flag and the hibernation flag are provided in any storage area in the memory system 2. However, they may be provided in, for example, the power control unit 12. The settings and confirmation of these flags are executed by the controller 3. After Step S106, the memory system 2 enters the state b (Step S107). Specifically, the controller 3 controls the power control unit 12 to turn off the second RAM 11.

In this manner, the memory system 2 transitions to the state b in which the management information has not been written to the non-volatile memory 121, and saved in the data cache 111 in the data storage unit 10. However, the address of the non-volatile memory 121, where the management information is saved, is allocated at this point in time, assuming a write to the non-volatile memory 121. Specifically, when the management information saved in the first RAM 5 or the second RAM 11 is copied to the data cache 111, the address is added to the management information and saved as the management information in the data cache 111. Consequently, it is possible to branch the next state transition destination depending on a subsequent command from the host 1. A description has been given here taking the data cache 111, the program buffer 131, and the non-volatile memory 121 connected to the program buffer 131 as examples. However, the same shall apply to another combination such as the data cache 11n, a program buffer connected to the data cache 11n, and the non-volatile memory 12n connected to the program buffer. Consequently, the time taken for the state transition to the hibernation state can be shortened compared with the states c and d.

(State b→State a)

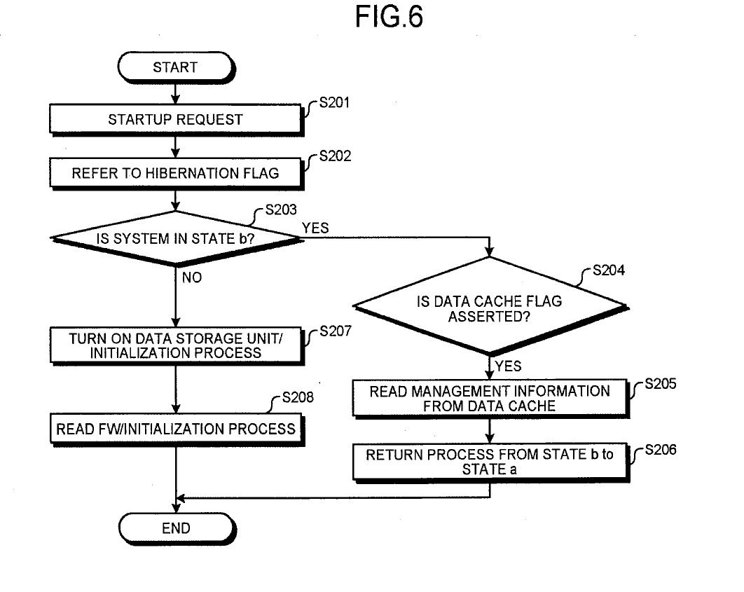

Next, a description is given of the progress of a return from the state b to the state a illustrated in the lower part of FIG. 3 with reference to the flowchart of FIG. 6. The flowchart of FIG. 6 is a flowchart that is also applicable to a case where an initial state is the state d other than the case where the initial state is the state b.

First, the host 1 issues a startup request (Step S201). Specifically, the host 1 notifies the power control unit 12 of the startup request. The power control unit 12 refers to the hibernation flag saved in the power control unit 12 or the like. The power control unit 12 turns on the second RAM 11. The power control unit 12 gives a restoration request to the controller 3. The controller 3 then refers to the hibernation flag (Step S202), and determines whether or not to be in the state b (Step S203). Specifically, it is determined whether or not the hibernation flag is asserted in Step S106 of FIG. 4. If the hibernation flag is asserted, it is determined to be in the state b (step S203: Yes), and execution proceeds to Step S204. If the hibernation flag is not asserted, it is determined to be in the state d (Step S203: No). The controller 3 turns on the data storage unit 10 to execute an initialization process (Step S207), and reads firmware out to execute the initialization process (Step S208).

In Step S204, it is determined whether or not the data cache flag is asserted. If the data cache flag is asserted (Step S204: Yes), execution proceeds to Step S205.

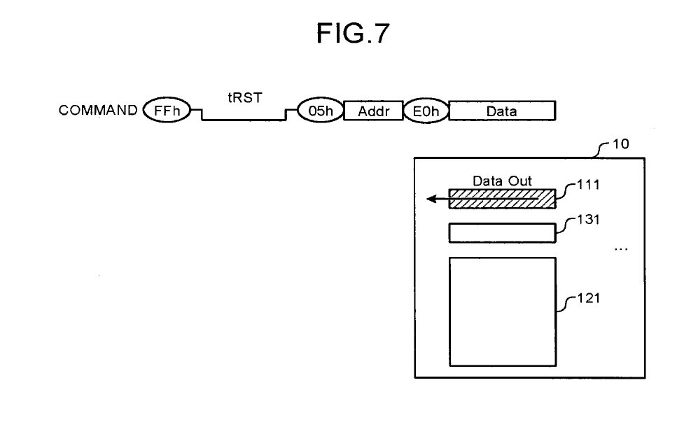

In Step S205, as illustrated in FIG. 7, the memory controller 6 issues, to the data storage unit 10, for example, a command “FFh” that interrupts the program sequence of a write operation. “tRST” is a device reset time during which the data storage unit 10 is reset. The memory controller 6 does not issue, to the data storage unit 10, for example, “10h” being the command to confirm a data write to the data storage unit 10 in Step S104. Therefore, the data storage unit 10 is halfway through a data write to the non-volatile memory 121. Therefore, the issue of the command “FFh” can cancel the state in the middle of the data write. A command to read the data in the data cache 111, for example, a “05h-Addr-E0h-Data” command, is subsequently issued as illustrated in FIGS. 3 and 7. A combination of “05h” and “E0h” means a random data output command. “Addr” is an address on the non-volatile memory 121 in which the management information is stored. “Data” represents the data saved in the data cache 111, that is, the management information. Therefore, the “05h-Addr-E0h-Data” command in the upper part of FIG. 7 causes the memory controller 6 to read the management information saved in the data cache 111 as illustrated in the lower part of FIG. 7 (Step S205). “Data Out” indicates that the data saved in the data cache 111 is read out. As in the lower part of FIG. 5, only the data cache 111, the program buffer 131, and the non-volatile memory 121 are illustrated in the data storage unit 10 in the lower part of FIG. 7. Consequently, the exhaustion of the non-volatile memory can be prevented. After Step S205, the return process from the state b to the state a is executed (Step S206). Specifically, the controller 3 controls the power control unit 12 to turn on the second RAM 11, and the memory system 2 is transitioned to the state a.

From the above, the shift from the state a to the state b and the return from the state b to the state a are executed only by a read from and a write to the data cache 111 without writing and reading data to and from the non-volatile memory 121. Hence, a high-speed state transition and a reduction of the load on the non-volatile memory 121 are achieved. Moreover, the data storage unit 10 is not turned off while in the state b. Accordingly, the processing time taken for power on/off of the data storage unit 10 and the power required for the processing can be reduced. If a time to turn off the data storage unit 10 is a short period of time, the transition to the state c may increase the processing time taken for the power on/off of the data storage unit 10 and the power consumed due to the processing compared to the cost of keeping the data storage unit 10 ON in the state b. Accordingly, the state b is a lower power state.

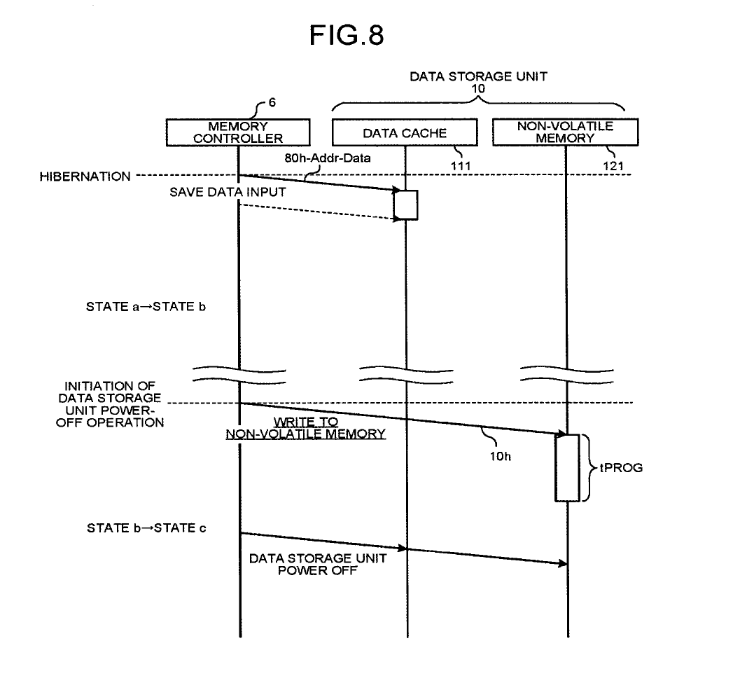

In this manner, the data cache 111 being the volatile memory of the data storage unit 10 is used as a destination to save the management information in the state b. Accordingly, power cannot be removed from the data storage unit 10. Hence, in the embodiment, the state b can be transitioned to the state c in which the data storage unit 10 is turned off to further reduce power consumption. FIG. 8 is a diagram illustrating the progress of data movement between the memory controller and the data storage unit upon the transition from the state a to the state b, and the transition from the state b to the state c. The upper part of FIG. 8 illustrates the progress of the transition from the state a to the state b, as in the upper part of FIG. 3. However, FIG. 8 illustrates the outline of the flow at the time of transitioning from the state b to the state c below from the initiation of a data storage unit power-off operation. Furthermore, the progress of the transition from the state b to the state c is described in detail below.

(State b→State c)

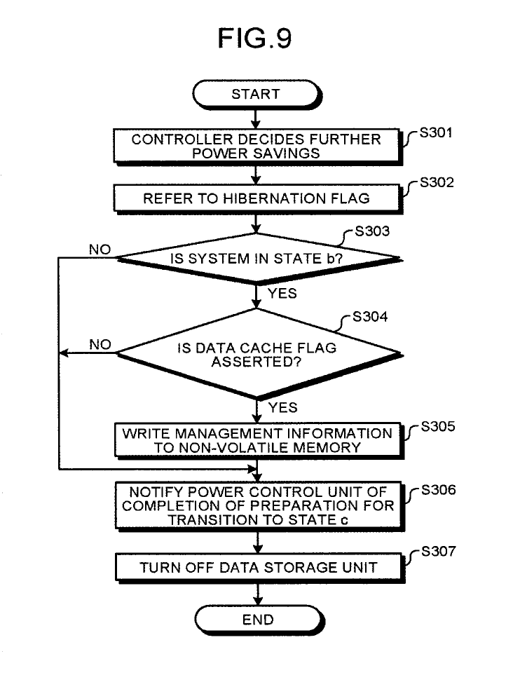

In the state b, the memory controller 6 does not issue, for example, “10h” being the command to confirm a data write to the data storage unit 10. Accordingly, the data storage unit 10 is in a state where the data write is uncompleted. In other words, the memory system 2 uses the state b as the hibernation state. The operation of the memory system 2 at the time of transitioning from the state b to the state c is described with reference to the flowchart of FIG. 9. The flowchart of FIG. 9 is a flowchart illustrating the operation of the memory system 2 at the time of decision, by the controller 3, of further power savings. The state at the start of the flowchart of FIG. 9 is a situation including cases being the state b and a state other than the state b.

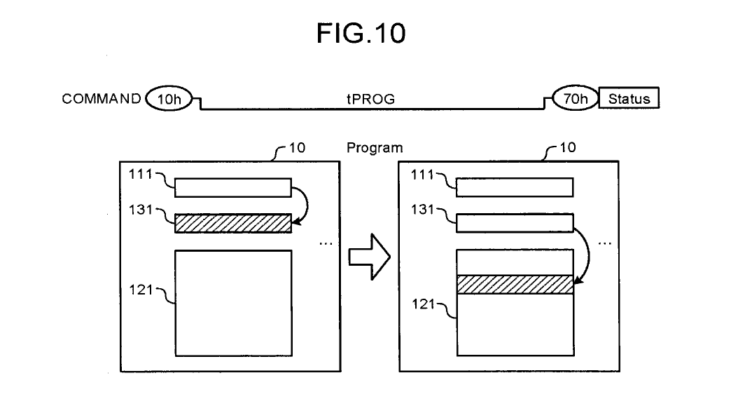

First, the controller 3 determines that it is necessary to power off the data storage unit 10 to promote further power savings (Step S301). Such a determination is made, for example, when a predetermined time has passed since the transition to the state b. Next, the controller 3 refers to the hibernation flag (Step S302), and determines whether or not to be in the state b (Step S303). If the hibernation flag is asserted, it is determined to be in the state b (Step S303: Yes), and execution proceeds to Step S304. In Step S304, it is determined whether or not the data cache flag is asserted. If the data cache flag is asserted (Step S304: Yes), the management information is saved in the data cache 111. Therefore, as illustrated in FIGS. 8 and 10, the memory controller 6 issues, to the data storage unit 10, a command such as “10h” being the command to confirm a data write to the data storage unit 10. The issue of the command “10h” permits the data to be made nonvolatile. “tPROG” represents a time during which the data is made nonvolatile. The data of the management information is written to the non-volatile memory 121 during “tPROG”. The lapse of the time “tPROG” is represented in the vertical direction in FIG. 8 and in the horizontal direction in the display of the command in the upper part of FIG. 10. Specifically, during “tPROG”, the management information of the data cache 111 is stored in the program buffer 131 as illustrated in the lower left part of FIG. 10, and the management information stored in the program buffer 131 is automatically written to the non-volatile memory 121 as illustrated in the lower right part of FIG. 10 (Step S305). “70h” illustrated in the upper part of FIG. 10 is a status read command, which is a command to confirm the state of the data storage unit 10 indicated by “Status” after “70h”. Therefore, the commands “10h”, “70h”, and “Status” in the upper part of FIG. 10 allow the management information illustrated in the lower part of FIG. 10 to be written to the non-volatile memory 121. As in the lower part of FIG. 5, only the data cache 111, the program buffer 131, and the non-volatile memory 121 are illustrated in the data storage unit 10 in the lower part of FIG. 10. After Step S305, if it is determined to be not in the state b (Step S303: No), and if the data cache flag is not asserted (Step S304: No), execution proceeds to Step S306. The controller 3 notifies the power control unit 12 that a preparation for the transition to the state c is complete. After Step S306, the power control unit 12 turns off the data storage unit 10 as illustrated in “DATA STORAGE UNIT POWER OFF” in the lower part of FIG. 8 (Step S307). The memory system 2 then transitions to the state c.

As described above, the save destination address of the non-volatile memory 121 is assigned in the management information of the data cache 111. Consequently, there is no need to once read the management information from the data cache 111 into the memory controller 6 and write the management information again to the non-volatile memory 121 via the data cache 111. In other words, a process can be performed in which the management information of the data cache 111 is written directly to the non-volatile memory 121. After the data is written to the non-volatile memory 121, the data storage unit 10 can be turned off.

As described above, if a predetermined condition is satisfied while in the state b, the management information saved in the data cache 111 may be discarded without transitioning from the state b to the state a or c, based on the determination of the controller 3. After the management information is discarded, transition is made to the state d. The predetermined condition is, for example, when there is no difference between the management information saved in the data cache 111 and the management information already written to the non-volatile memory 121, or when the management information is log information that is determined to be not necessary to be made nonvolatile.

The embodiment provides the state b being an intermediate hibernation state in which power is removed from the DRAM, but the data storage unit 10 remains powered. Consequently, it becomes possible to maintain this state until the next state is decided and to make a selection, as the next state to be transitioned, from the state c being the deeper hibernation state in which the management information is written to the non-volatile memory, and the state a being the normal operating state in which power to the DRAM is restored to read back the management information.

When power is removed from the data storage unit 10 to shift from the state b to the state c being the deeper hibernation state, the management information is written to the non-volatile memory. Accordingly, power is removed from the data storage unit 10. Moreover, as the data storage unit 10 is not turned off in the state b, the return process from the state b to the state a is faster than the return from the state c to the state a. The intermediate hibernation state that can transition at high speeds is provided to respond to a detailed hibernation request frequently given from the host in a short period of time. Accordingly, it becomes possible to reduce power consumption and increase the speed of the hibernation/return process. Moreover, it also becomes possible to reduce the amount of access to the non-volatile memory and reduce the load.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a data storage unit including a volatile storage unit and a non-volatile memory where data is read and written via the volatile storage unit;
a volatile memory;
a controller configured to control the reading and writing of data from and to the data storage unit; and
a power control unit configured to control power supply to the controller, the volatile memory, and the data storage unit, wherein
the controller switches modes including a normal operating mode, a first mode, and a second mode, the normal operating mode being a mode in which power resources of the volatile memory, the data storage unit, and the power control unit are all ON, the first mode being a mode in which the power resource of the volatile memory is OFF, and the power resources of the data storage unit and the power control unit are both ON, the second mode being a mode in which the power resources of the volatile memory and the data storage unit are both OFF, and the power resource of the power control unit is ON, and
upon receiving a low power consumption instruction command from a host, the controller stores management information into the volatile storage unit, the management information including information to return to the normal operating mode, and shifts the state of the memory system from the normal operating mode to the first mode.

2. The memory system according to claim 1,
wherein when shifting from the first mode to the normal operating mode, the controller reads the management information from the volatile storage unit.

3. The memory system according to claim 1,
wherein upon receiving the low power consumption instruction command from the host while writing data to the non-volatile memory, the controller completes the writing of the data to the non-volatile memory and then shifts from the normal operating mode to the first mode.

4. The memory system according to claim 1,
wherein when a predetermined condition is satisfied, the controller discards the management information stored in the volatile storage unit.

5. The memory system according to claim 4,
wherein the predetermined condition is a case where the management information saved in the volatile storage unit is the same as the management information written to the non-volatile memory.

6. The memory system according to claim 2, wherein
the power control unit having a first flag and a second flag, the first flag indicating whether or not the management information is saved in the volatile storage unit, the second flag indicating whether or not to be in the first mode, and
when the first and the second flags are both asserted, the controller reads the management information from the volatile storage unit.

7. The memory system according to claim 1,
wherein upon a predetermined time having passed while being in a state that is the first mode, the controller shifts the state of the memory system to the second mode.

8. The memory system according to claim 7,
wherein when shifting to the second mode, the controller writes the management information to the non-volatile memory, and after the write to the non-volatile memory, causes the power control unit to turn off the data storage unit.

9. The memory system according to claim 8,
wherein the volatile storage unit includes a data cache configured to save the management information, and a program buffer configured to transfer the management information to the non-volatile memory after receiving the management information from the data cache.

10. The memory system according to claim 9,
wherein the data storage unit is a NAND flash memory.

11. A control method of a memory system, the memory system including:
a data storage unit having a volatile storage unit and a non-volatile memory where data is read and written via the volatile storage unit;
a volatile memory;
a controller configured to control the reading and writing of data from and to the data storage unit; and
a power control unit configured to control power supply to the controller, the volatile memory, and the data storage unit, the memory system including:
the control method comprising:
storing, upon receiving a low power consumption instruction command from a host, management information into the volatile storage unit, the management information including information to return to a normal operating mode, the normal operating mode being a mode in which power resources of the volatile memory, the data storage unit, and the power control unit are all ON; and
shifting the state of the memory system from the normal operating mode to a first mode, the first mode in which the power resource of the volatile memory is OFF, and the power resources of the data storage unit and the power control unit are both ON.

12. The control method of the memory system according to claim 11, further comprising:
reading, when shifting from the first mode to the normal operating mode, the management information from the volatile storage unit.

13. The control method of the memory system according to claim 11, further comprising:
completing, upon receiving the low power consumption instruction command from the host while writing data to the non-volatile memory, the writing of the data to the non-volatile memory, and
shifting from the normal operating mode to the first mode.

14. The control method of the memory system according to claim 11, further comprising:
discarding, when a predetermined condition is satisfied, the management information stored in the volatile storage unit.

15. The control method of the memory system according to claim 14,
wherein the predetermined condition is a case where the management information saved in the volatile storage unit is the same as the management information written to the non-volatile memory.

16. The control method of the memory system according to claim 11,
wherein the power control unit having a first flag and a second flag, the first flag indicating whether or not the management information is saved in the volatile storage unit, the second flag indicating whether or not to be in the first mode, and
the control method further comprising:
reading, when the first and the second flags are both asserted, the management information from the volatile storage unit.

17. The control method of the memory system according to claim 11, further comprising:
shifting, upon a predetermined time having passed while being in a state that is the first mode, the state of the memory system to a second mode, the second mode being a mode in which the power resources of the volatile memory and the data storage unit are both OFF, and the power resource of the power control unit is ON.

18. The control method of the memory system according to claim 12, further comprising:
writing, when shifting to the second mode, the management information to the non-volatile memory; and
causing, after the write to the non-volatile memory, the power control unit to turn off the data storage unit.

19. The control method of the memory system according to claim 11,
wherein the volatile storage unit includes a data cache configured to save the management information, and a program buffer configured to transfer the management information to the non-volatile memory after receiving the management information from the data cache.

20. The control method of the memory system according to claim 11,
wherein the data storage unit is a NAND flash memory.
